(19) United States
(12) Patent Application Publication
(10) Pub. No.: US 2015/0296620 A1
(43) Pub. Date: Oct. 15, 2015

(54) CIRCUIT BOARD, METHOD FOR MANUFACTURING CIRCUIT BOARD, ELECTRONIC COMPONENT PACKAGE, AND METHOD FOR MANUFACTURING ELECTRONIC COMPONENT PACKAGE

(71) Applicant: Samsung Electro-Mechanics Co., Ltd., Suwon (KR)

(72) Inventors: Doo Hwan LEE, Daejeon (KR); Hyung Gi Ha, Daejeon (KR)

(73) Assignee: Samsung Electro-Mechanics Co., Ltd., Suwon (KR)

(21) Appl. No.: 14/460,918

(22) Filed: Aug. 15, 2014

(30) Foreign Application Priority Data
Apr. 10, 2014 (KR) 10-2014-0042930

(51) Int. Cl. H05K 1/14; H05K 1/11; H05K 3/34; H05K 1/18

(52) U.S. Cl. CPC H05K 1/144; H05K 1/181; H05K 1/183; H05K 1/111; H05K 3/341; H05K 3/3484; H05K 2201/10734; H05K 2201/10318; H05K 2203/04

(57) ABSTRACT

A circuit board includes an insulating material; a conductive pattern formed on at least one surface of the insulating material; and a connection pin adapted for electrical connection with an external apparatus, attached to the one surface, and made of a metal.

### CROSS-REFERENCE TO RELATED APPLICATIONS

This application claims the foreign priority benefit under 35 U.S.C. Section 119 of Korean Patent Application Serial No. 10-2014-0042930, entitled “Circuit Board, Method for Manufacturing Circuit Board, Electronic Component Package, and Method for Manufacturing Electronic Component Package,” filed on Apr. 10, 2014, which is hereby incorporated by reference in its entirety into this application.

### BACKGROUND

1. Field

Embodiments of the present invention relate to a circuit board, a method for manufacturing a circuit board, an electronic component package, and a method for manufacturing an electronic component package.

2. Description of the Related Art

In accordance with the trend toward lightness, miniaturization, increased speed, increased functionality, and performance improvement of electronic devices, multilayer board technologies in which a plurality of wiring layers are formed on a printed circuit board (PCB) have been developed.

In packaging semiconductors used in mobile electronic devices a plurality of packages can be combined with each other. For example, an application processor (AP) mounted in a smart phone can be in a package on package (POP) configuration together with a memory element or the like.

Meanwhile, as disclosed in U.S. Pat. No. 8,049,114, U.S. Pat. No. 6,778,404, and the like, these packages generally have been connected to each other by a solder ball.

To transmit more data between the packages connected to each other at a more rapid speed, more connection paths between the packages should be implemented. In addition, in order to be in accordance with the trend toward the miniaturization of the electronic device, the size of the package should be decreased. Therefore, in order to satisfy both of these two requirements, the connection paths between the packages should be made finer.

However, in methods of applying a general solder ball bonding scheme according to the related art reduction in the pitches of solder balls is limited due to isotropy of the solder balls. Therefore, there is a limitation when attempting to make fine connection paths between the packages.

### SUMMARY

An aspect of the present invention is to provide a circuit board, a method for manufacturing a circuit board, an electronic component package, and a method for manufacturing an electronic component package capable of making connection paths between circuit boards fine.

Another aspect of the present invention is to provide a circuit board, a method for manufacturing a circuit board, an electronic component package, and a method for manufacturing an electronic component package capable of improving signal transfer characteristics between circuit boards.

Embodiments of the present invention are not limited to the above-mentioned aspects and benefits. That is, other aspects and benefits that are not mentioned, including those that may be understood by those skilled in the art, are also within the scope of this disclosure.

According to an exemplary embodiment of the present invention, a circuit board includes: an insulating material; a conductive pattern formed on at least one surface of the insulating material; and a connection pin formed for electrical connection with an external apparatus, attached to the one surface, and made of a metal material.

An area of an upper surface of the connection pin may be different from that of a lower surface of the connection pin.

A vertical cross section of the connection pin may have at least one of a T shape and a trapezoidal shape.

The circuit board may further include an electronic component surface-mounted on or embedded therein.

The circuit board may further include a ball grid array provided on a lower surface thereof.

According to another exemplary embodiment of the present invention, there is provided a method for manufacturing a circuit board including an insulating material and a conductive pattern formed on at least one surface of the insulating material, including: coupling one surface of a connection pin formed for electrical connection with an external apparatus and made of a metal material to an upper surface of the circuit board, wherein the connection pin has an area larger on one surface thereof than on the other surface thereof and is manufactured in advance at a large size before being coupled to the upper surface of the circuit board.

The method may further include coupling a lower surface of an additional circuit board to the other surface of the connection pin.

The circuit board may further include an electronic component surface-mounted on or embedded therein.

At least one of the circuit board and the additional circuit board may further include an electronic component surface-mounted on or embedded therein.

According to still another exemplary embodiment of the present invention, there is provided an electronic component package including a circuit board including an insulating material and a conductive pattern formed on at least one surface of the insulating material and an electronic component, including: a first electronic component package including a first electronic component and at least one first connecting pad provided on one surface thereof; and at least one connection pin having a first surface coupled to the first connecting pad and a second surface, which is an opposite surface to the first surface, formed integrally using a conductive material, and having a pin shape in which an area of the first surface is different from that of the second surface.

The first electronic component may be mounted on a surface of the first electronic component package.

The first electronic component may be mounted in a first region of the first electronic component package, and the first connecting pad may be provided in a region except for the first region.

The connection pin may include: a first part having a cylindrical shape having the first surface as a lower surface; and a second part having a cylindrical shape having the second surface as an upper surface, the first and second part being formed integrally with each other.

The electronic component package may further include a plating layer or a solder layer provided between the first surface and the first connecting pad or between the second surface and a second connecting pad.

The first electronic component may be embedded in the first electronic component package.

The first electronic component package may include a core part in which a recess part or a cavity is formed and a buildup part provided on at least one surface of the core part, and at least a portion of the first electronic component may be inserted into the recess part or the cavity.

The first connecting pad may be provided in a region including at least a portion of a region above the first electronic component.

The connection pin may be formed in advance using a material having a melting point higher than about 280° C.

According to yet still another exemplary embodiment of the present invention, there is provided a method for manufacturing the electronic component package as described above, including: providing the first electronic component package; and fixing the first surface to the first connecting pad, wherein the first surface has an area larger than that of the second surface.

The fixing of the first surface to the first connecting pad may be performed by supplying hot wind having a temperature of about 280° C. or less after the first surface contacts a first solder paste in a state in which the first solder paste is applied onto the first connecting pad.

The method may further include coupling a second electronic component package including a second electronic component and at least one second connecting pad provided on one surface thereof, wherein the coupling of the second electronic component package is performed by supplying hot wind having a temperature of about 280° C. or less after the second connecting pad contacts a second solder paste in a state in which the second solder paste is applied onto the second surface.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a cross-sectional view schematically showing an electronic component package according to an exemplary embodiment of the present invention;

FIG. 2 is a cross-sectional view schematically showing an electronic component package according to another exemplary embodiment of the present invention;

FIG. 3 is a cross-sectional view schematically showing an electronic component package according to another exemplary embodiment of the present invention;

FIG. 4 is a cross-sectional view schematically showing an electronic component package according to another exemplary embodiment of the present invention;

FIG. 5 is a cross-sectional view schematically showing an electronic component package according to another exemplary embodiment of the present invention;

FIG. 6A is a cross-sectional view schematically showing a state in which a first electronic component package is provided according to an exemplary embodiment of the present invention;

FIG. 6B is a cross-sectional view schematically showing a state in which a first solder paste is applied according to an exemplary embodiment of the present invention;

FIG. 6C is a cross-sectional view schematically showing a state in which a first surface of a connection pin contacts a first solder paste according to an exemplary embodiment of the present invention;

FIG. 6D is a cross-sectional view schematically showing a state in which a second solder paste is applied onto a second surface of a connection pin according to an exemplary embodiment of the present invention; and

FIG. 6E is a cross-sectional view schematically showing a state in which a second connecting pad contacts a second solder paste according to an exemplary embodiment of the present invention.

### DESCRIPTION OF EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Meanwhile, like reference numerals throughout the description denote like elements.

Terms used in the present specification are for explaining exemplary embodiments rather than limiting the present invention. Unless explicitly described to the contrary, a singular form includes a plural form in the present specification. The terms “comprise” and variations such as “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but are not necessarily limited thereto. For example, it may be understood that these terms are compatible with each other under an appropriate environment so that exemplary embodiments of the present invention to be described below may be operated in a sequence different from a sequence shown or described herein. Likewise, in the case in which it is described that a method includes a series of steps, a sequence of described steps is not necessarily a sequence in which these steps may be executed. That is, any described step may be omitted or any another step that is not described herein may be added to the method.

In the specification and the claims, terms such as “left”, “right”, “front”, “rear”, “top”, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

In the specification and the claims, the phrase “at least one of A, B and C” indicates an alternative expression that means that one or more of A, B and C may be used.

In the specification and the claims, the terms “T shape” and “trapezoidal shape” do not require a particular orientation of the shape unless expressly stated otherwise.

Hereinafter, a configuration and an acting effect of exemplary embodiments of the present invention will be described in more detail with reference to the accompanying drawings.

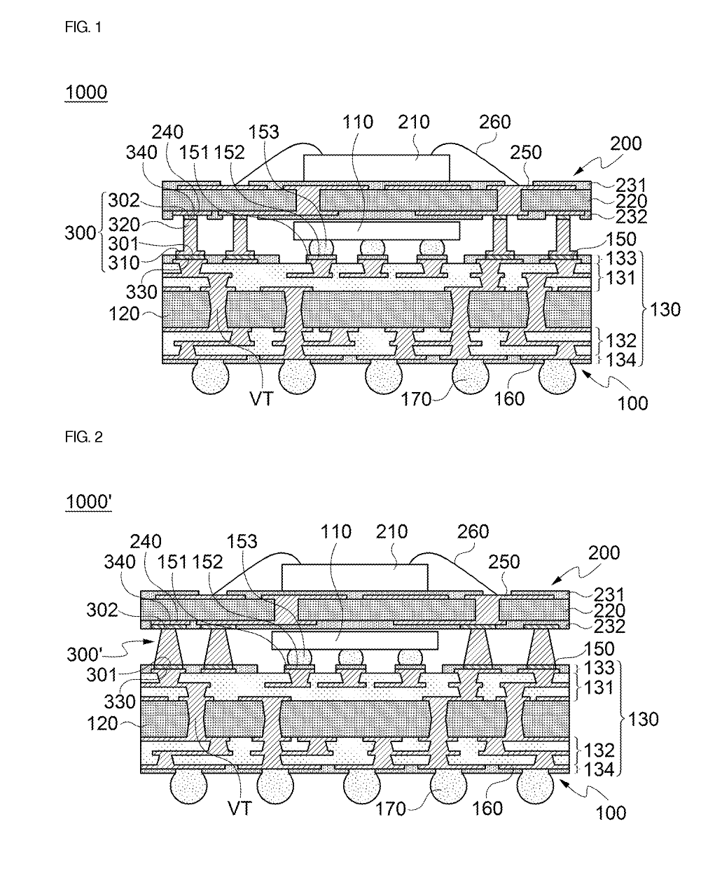

FIG. 1 is a cross-sectional view schematically showing an electronic component package 1000 according to an exemplary embodiment of the present invention; and FIGS. 2 to 5 are cross-sectional views schematically showing electronic component packages 1000′, 2000, 3000, and 3000′ according to other exemplary embodiments of the present invention.

Referring to FIGS. 1 to 3, the electronic component package 1000 according to an exemplary embodiment of the present invention may include a first electronic component package 100 and connection pins 300, and may further include a second electronic component package 200 coupled to the connection pin 300, if necessary.

Here, the first electronic component package 100 may be called a circuit board, and the second electronic component package 200 may be called an additional circuit board.

The first electronic component package 100 may include a first electronic component 110, wherein the first electronic component 110 may be an active element such as an integrated circuit (IC), an application processor (AP), or the like, or a passive element such as a capacitor, an inductor, or the like.

The second electronic component package 200 may include a second electronic component 210.

In an exemplary embodiment of the present invention, the first electronic component package 100 or the second electronic component package 200 may be implemented as a multilayer board.

For example, as shown in FIG. 1, the first electronic component package 100 may be a multilayer board including a core part 120 and a buildup part 130 and implemented as a plurality of layers.

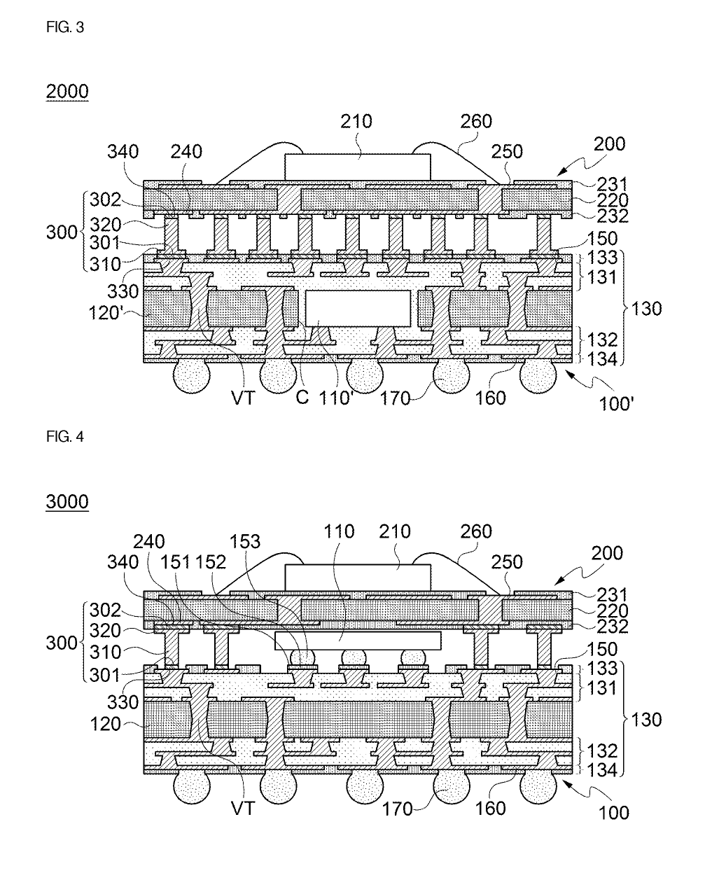

In addition, as shown in FIG. 3, a core part 120′ may be provided with a cavity C, and a first electronic component 110′ may be inserted into the cavity C. Here, the cavity C means a region penetrating through both surfaces of the core part 120′ and may be replaced by a recess part (not shown) that does not penetrate through both surfaces of the core part 120′, if necessary.

Meanwhile, the buildup part 130 may be provided on one surface or both surfaces of the core part 120. In the latter case, as shown in FIG. 1, the buildup part 130 may be divided into an upper buildup layer 131 and a lower buildup layer 132 based on the core part 120.

In addition, the upper buildup layer 131 and the lower buildup layer 132 may be electrically connected to each other through a through-via VT penetrating through the core part 120.

Further, an upper surface of the upper buildup layer 131 may be provided with a first connecting pad 150, and may be further provided with a first upper solder resist 133 exposing a portion of the first connecting pad 150.

Likewise, a lower surface of the lower buildup layer 132 may be provided with a first connection pad 160, and may be further provided with a first lower solder resist 134 exposing a portion of the first connection pad 160.

In addition, solder balls may be coupled to at least portions of the first connection pad 160 to implement a ball grid array (BGA) 170.

In an exemplary embodiment of the present invention, the first electronic component 110 may be surface-mounted on or be embedded in the first electronic component package 100.

As shown in FIG. 1, in the case in which the first electronic component 110 is surface-mounted, the first electronic component 110 may be electrically connected to the upper buildup layer 131. Here, the upper surface of the upper buildup layer 131 may be provided with a connecting terminal 151 for connection with the first electronic component 110. In addition, the first connecting pad 150 described above may be provided in a region except for a region in which the first electronic component 110 is surface-mounted, and the connection pin 300 may be coupled to the first connecting pad 150.

Although the connecting terminal 151 and the first connecting pad 150 are separately named in order to assist the understanding for a coupling relation with the connection pin 300, the connecting terminal 151 and the first connecting pad 150 may be implemented by the same process by forming conductive patterns on a surface of the upper buildup layer 131. In addition, although the case in which the first upper solder resist 133 is not provided in the vicinity of the connecting terminal 151 has been shown in FIG. 3, an additional solder resist (not shown) exposing a portion of the connecting terminal 151 may be further provided, if necessary, wherein the additional solder resist may be provided together with the first upper solder resist 133 using a process of forming the first upper solder resist 133.

In an exemplary embodiment of the present invention, a lower surface of the first electronic component 110 may be provided with a plurality of first solder balls 153, which may be coupled to the connecting terminal 151 through an adhering layer 152.

Next, as shown in FIG. 3, in the case in the first electronic component 110′ is embedded, the first electronic component 110′ may be inserted into the cavity C or the recess part provided in the core part 120. In addition, a via may be connected to an electrode (not shown) of the first electronic component 110′.

In an exemplary embodiment of the present invention, in the case in which the first electronic component 110′ is embedded, the first connecting pad 150 may also be provided in a region above a region in which the first electronic component 110′ is embedded. In addition, since the connection pins 300 may be coupled to the first connecting pad 150, the case shown in FIG. 3 may be more advantageous in increasing the number of connection pins 300 as compared with the case shown in FIG. 1 and may be more advantageous in that a larger spare space may be secured as compared with the case shown in FIG. 1 in the case in which the same number of connection pins 300 are implemented.

Further, in the case of the electronic component package 1000 shown in FIG. 1, since the first electronic component 110 is positioned between the first electronic component package 100 and the second electronic component package 200, the first electronic component package 100 and the second electronic component package 200 need to be spaced apart from each other by a distance equal to or larger than a height of the first electronic component 110. Therefore, a height of the connection pin 300 may also be determined correspondingly.

Here, in the case in which connection is implemented by growing the connection pin 300 in a plating scheme, as the height of the connection pin 300 is increased, it is more difficult to implement a resist utilized in a plating process and a plating time is increased, such that productivity may be decreased and a manufacturing cost may be increased.

In order to solve the above-mentioned problems, the connection pin 300 according to an exemplary embodiment of the present invention may be made of a material such as copper, or the like, having high conductivity and may be formed integrally in advance. That is, the connection pin 300 is not formed on the first electronic component package 100 or the second electronic component package 200 in a scheme such as a plating scheme, a printing scheme, an injecting scheme, or the like, but may be provided in a state in which it is prepared in advance and be then coupled between the first electronic component package 100 and the second electronic component package 200.

Meanwhile, in the case of the electronic component package 2000 shown in FIG. 3, since the first electronic component 110′ is embedded in a first electronic component package 110′, a spacing distance between the first electronic component package 100′ and the second electronic component package 200 may be decreased as compared with the case shown in FIG. 1. Therefore, a height of the connection pin 300 may be decreased as compared with the case shown in FIG. 1.

Next, the second electronic component package 200 may include an insulating part 220, a second upper solder resist 231, a second lower solder resist 232, a second connecting pad 240, and a second connection pad 250. In addition, the second electronic component package 200 may include the second electronic component 210 as described above.

Here, the second electronic component 210 may be an active element such as an integrated circuit (IC), a memory element, or the like. Here, the second electronic component 210 may be connected to the second connection pad 250 in various schemes to be electrically conducted thereto. The case in which the second connection pad 250 and the second electronic component 210 are electrically connected to each other by a wire 260 has been shown in FIG. 1, and the like.

Meanwhile, the first electronic component package 100 and the second electronic component package 200 may be connected to each other by the connection pin 300. A structure in which the second electronic component package 200 is positioned on the first electronic component package 100 and is connected to the first electronic component package 100 by the connection pin 300 has been shown in FIG. 1, and the like. This structure may be called a package on package (POP).

In an exemplary embodiment of the present invention, the connection pin 300 may have a first surface 301 and a second surface 302. Referring to FIG. 1, and the like, it may be understood that the first surface 301 indicates a lower surface of the connection pin 300 and the second surface 302 indicates an upper surface of the connection pin 300.

In addition, the first surface 301 may be coupled to the first connecting pad 150 described above, and the second surface 302 may be coupled to the second connecting pad 240 described above. Here, a first solder layer 330 may be provided between the first surface 301 and the first connecting pad 150 and a second solder layer 340 may be provided between the second surface 302 and the second connecting pad 240 to allow the connection pin 300 and the first and second connecting pads 240 to be firmly fixed to each other and be conducted to each other.

In an exemplary embodiment of the present invention, the first surface 301 may have an area larger than that of the second surface 302. That is, the connection pin 300 may have a shape in which an upper portion thereof is narrow and a lower portion thereof is wide.

In addition, the connection pin 300 may have an overturned (upside down) T shape or a vertical cross section of a connection pin 300′ may have a trapezoidal shape.

The case in which the connection pin 300 has the overturned T shape has been shown in FIG. 1, and the case in which the vertical cross section of the connection pin 300′ has the trapezoidal shape has been shown in FIG. 2. Here, in the case in which the connection pin 300 has the overturned T shape, the connection pin 300 may be implemented so that a first part 310 and a second part 320 are formed integrally with each other. In addition, the first part 310 may have a cylindrical shape having the first surface 301 as a lower surface, and the second part 320 may have a cylindrical shape having the second surface 302 as an upper surface.

As described above, the connection pin 300 has the shape in which the upper portion thereof is narrow and the lower portion thereof is wide, such that efficiency of a process of fixing the connection pin 300 between the first electronic component package 100 and the second electronic component package 200 in a process of manufacturing an electronic component package 1000 to be described above may be improved. A principle in which the efficiency is improved will be described below.

Meanwhile, a general solder ball needs to be subjected to a reflow process, or the like, in order to be attached to a target object. In this case, the solder ball is heated, such that flexibility is increased. As a result, the solder ball having a spherical shape before being heated is partially collapsed, such that a short-circuit phenomenon that the collapsed solder ball contacts another solder ball adjacent thereto or another pattern adjacent to the target object may occur. Particularly, as an interval between the solder balls becomes narrow, a risk that the short-circuit phenomenon will occur may be increased. In addition, as a height of the solder ball becomes high, this spread phenomenon may be further intensified.

However, even though the connection pin 300 according to an exemplary embodiment of the present invention is heated by a reflow process, a change in flexibility thereof is not larger than that of a general solder ball, such that the spread phenomenon may be significantly decreased.

Therefore, the first electronic component package 100 and the second electronic component package 200 are connected to each other by the connection pin 300, thereby making it possible to make pitches of connection paths finer.

In addition, the pitches of the connection paths are decreased, thereby making it possible to secure more connection paths in a narrower area. Therefore, it is possible to improve signal transfer characteristics while decreasing an area of the electronic component package.

Meanwhile, in the case in which the connection pin 300 is made of a copper material, conductivity may be improved as compared with an existing solder ball, such that signal transfer characteristics may be further improved.

FIGS. 4 and 5 are views schematically showing an electronic component package according to another exemplary embodiment of the present invention.

In an exemplary embodiment shown in FIGS. 4 and 5, the connection pin 300 has a shape in which an upper portion thereof is wide and a lower portion thereof is narrow unlike an exemplary embodiment shown in FIGS. 1 to 3. In a method for manufacturing an electronic component package according to an exemplary embodiment of the present invention, a wide surface of the connection pin 300 may be first fixed to one electronic component package, and a narrow surface of the connection pin 300 may be fixed to another electronic component package. That is, the wide surface of the connection pin 300 is first fixed, thereby making it possible to improve stability of the connection pin in a process of connecting the electronic component packages to each other using the connection pin 300. As a result, manufacturing efficiency of the electronic component package may be improved. Therefore, in the case in which the connection pin 300 is first fixed to the first electronic component package 100, it is advantageous that an area of the first surface 301 is wider than that of the second surface 302, and in the case in which the connection pin 300 is first fixed to the second electronic component package 200, it is advantageous that an area of the second surface 302 is wider than that of the first surface 301. In this viewpoint, an exemplary embodiment shown in FIGS. 4 and 5 may be meaningful.

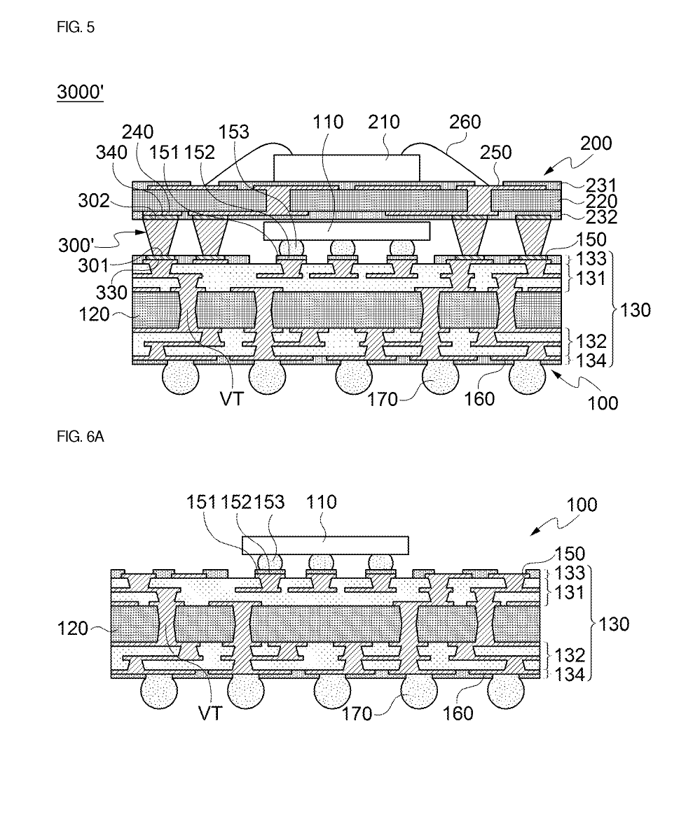

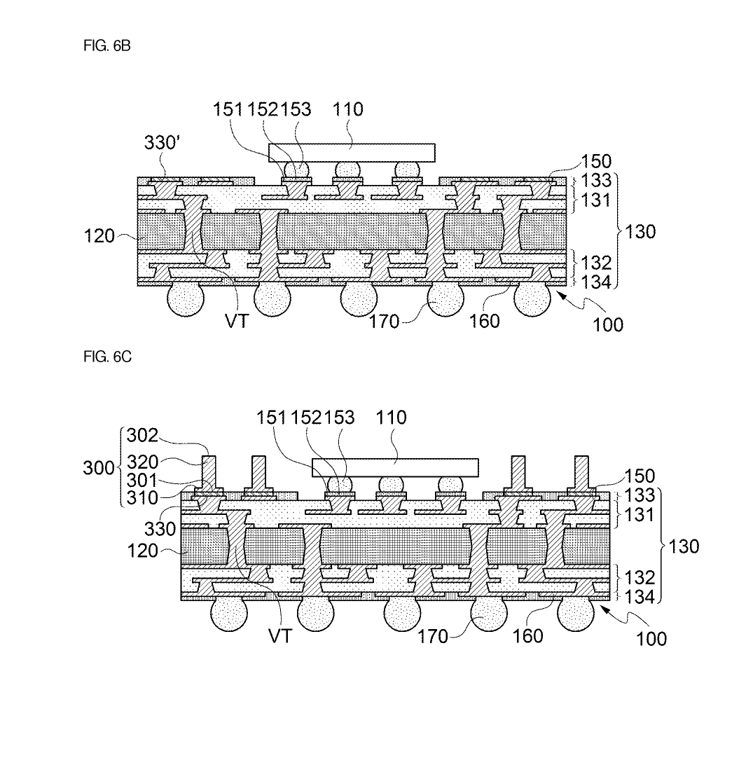

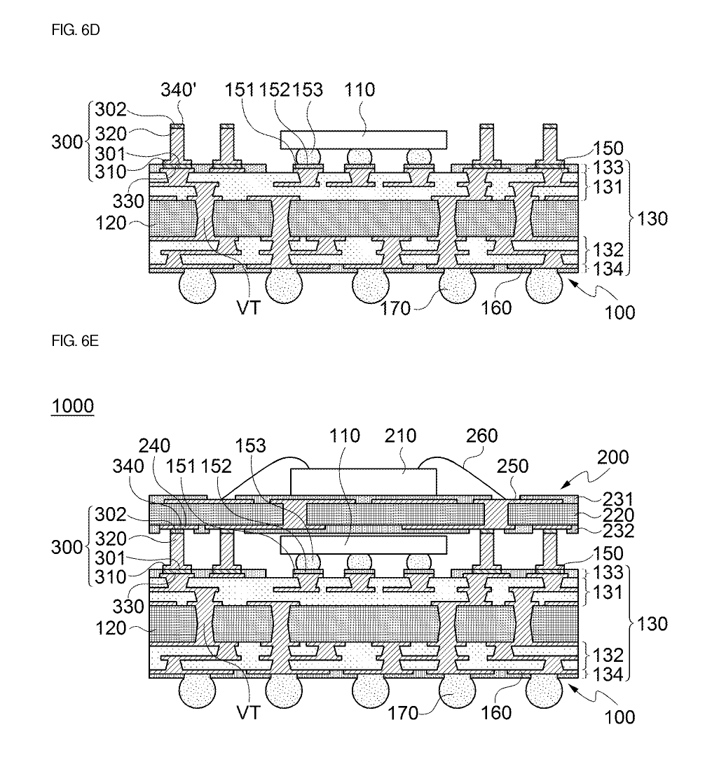

FIGS. 6A to 6E are cross-sectional views showing a process of manufacturing an electronic component package 1000 according to an exemplary embodiment of the present invention.

Hereinafter, a method for manufacturing an electronic component package 1000 according to an exemplary embodiment of the present invention will be described with reference to FIGS. 6A to 6E.

First, FIG. 6A is a cross-sectional view schematically showing a state in which a first electronic component package 100 is provided according to an exemplary embodiment of the present invention. Referring to FIG. 6A, the first electronic component package 100 including the first electronic component 110 may be provided. Here, although a state in which the first electronic component 110 is surface-mounted has been shown in FIG. 6A, the first electronic component 110 may also be embedded as shown in FIG. 3.

Meanwhile, in the case in which the first electronic component 110 is surface-mounted, the first connecting pad 150 may be provided in a region except for a region above or below the first electronic component 110.

Next, FIG. 6B is a cross-sectional view schematically showing a state in which a first solder paste 330′ is applied according to an exemplary embodiment of the present invention; and FIG. 6C is a cross-sectional view schematically showing a state in which a first surface 301 of a connection pin 300 contacts a first solder paste 330′ according to an exemplary embodiment of the present invention.

Referring to FIGS. 6B and 6C, after the first solder paste 330′ is applied onto a surface of the first connecting pad 150, the connection pin 300 may be coupled to the first connecting pad. Therefore, the connection pin 300 may allow an electrical signal to smoothly pass therethrough while being firmly fixed to the first connecting pad 150. Here, the first surface 301 of the connection pin 300 is coupled to the first solder paste 330′, and the first solder paste 330′ is hardened to form the first solder layer 330. In addition, tin plating may be performed instead of applying the first solder paste 330′.

FIG. 6D is a cross-sectional view schematically showing a state in which a second solder paste 340′ is applied onto a second surface 302 of a connection pin 300 according to an exemplary embodiment of the present invention; and FIG. 6E is a cross-sectional view schematically showing a state in which a second connecting pad 240 contacts a second solder paste 340′ according to an exemplary embodiment of the present invention.

Referring to FIGS. 6D and 6E, the second solder paste 340′ may be applied onto the second surface 302 of the connection pin 300. In this state, the second electronic component package 200 may be coupled to the connection pin 300 so that the second connecting pad 240 contacts the second solder paste 340′. Here, the second solder paste 340′ is hardened to form the second solder layer 340.

Here, the second solder paste 340′ may be applied onto the second connecting pad 240. In this case, although not shown, the first electronic component package 100 may be overturned so that the second surface 302 of the connection pin 300 is directed downwardly in a state in which the second connecting pad 240 is directed upwardly, such that it may be coupled to the second electronic component package 200. In addition, the case in which the second solder paste 340′ is applied onto the second connecting pad 240 may be slightly more advantageous in securing uniformity of heights of the connection pins 300 and precision of positions of the connection pins 300.

According to exemplary embodiments of the present invention, it is possible to make connection paths between packages fine, improve signal transfer characteristics between the packages, and improve manufacturing efficiency.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A circuit board comprising:
an insulating material;
a conductive pattern formed on at least one surface of the insulating material; and
a connection pin adapted for electrical connection with an external apparatus, attached to the one surface, and made of a metal material.

2. The circuit board according to claim 1, wherein an area of a first surface of the connection pin is different from that of a second surface of the connection pin, the first surface being opposite to the second surface, and
one of the first surface and the second surface is attached to the one surface of the insulating material.

3. The circuit board according to claim 1, wherein a vertical cross section of the connection pin has at least one of a T shape and a trapezoidal shape.

4. The circuit board according to claim 1, further comprising an electronic component surface-mounted on or embedded in the circuit board.

5. The circuit board according to claim 1, further comprising a ball grid array provided on a lower surface of the circuit board.

6. A method for manufacturing a circuit board including an insulating material and a conductive pattern formed on at least one surface of the insulating material, comprising:
coupling one surface of a connection pin to an upper surface of the circuit board, the connection pin being adapted for electrical connection with an external apparatus, made of a metal, having an area larger on one surface thereof than on another surface thereof, and having been manufactured in advance before being coupled to the upper surface of the circuit board.

7. The method according to claim 6, further comprising coupling a lower surface of an additional circuit board to the other surface of the connection pin.

8. The method according to claim 6, wherein the circuit board further includes an electronic component surface-mounted on or embedded therein.

9. The method according to claim 7, wherein at least one of the circuit board and the additional circuit board further includes an electronic component surface-mounted on or embedded therein.

10. An electronic component package comprising:
a first electronic component package including
an insulating material,
a conductive pattern formed on at least one surface of the insulating material, and
at least one first connecting pad provided on one surface of the first electronic component package;
a first electronic component; and
at least one connection pin having a first surface coupled to the first connecting pad, having a second surface opposite to the first surface, formed integrally using a conductive material, and having a pin shape in which an area of the first surface is different from that of the second surface.

11. The electronic component package according to claim 10, wherein the first electronic component is mounted on a surface of the first electronic component package.

12. The electronic component package according to claim 11, wherein the first electronic component is mounted in a first region of the first electronic component package, and the first connecting pad is provided in a region except for the first region.

13. The electronic component package according to claim 12, wherein each of the at least one connection pin includes:
a first part having a cylindrical shape having the first surface as a lower surface; and
a second part having a cylindrical shape having the second surface as an upper surface, the first and second part being formed integrally with each other.

14. The electronic component package according to claim 13, further comprising a plating layer or a solder layer provided between the first surface and the first connecting pad or on the second surface.

15. The electronic component package according to claim 10, wherein the first electronic component is embedded in the first electronic component package.

16. The electronic component package according to claim 15, wherein the first electronic component package includes a core part in which a recess part or a cavity is formed and a buildup part provided on at least one surface of the core part, and
at least a portion of the first electronic component is inserted into the recess part or the cavity.

17. The electronic component package according to claim 16, wherein the first connecting pad is provided in a region including at least a portion of a region above the first electronic component.

18. The electronic component package according to claim 15, wherein the at least one connection pin is positioned above the embedded first electronic component.

19. The electronic component package according to claim 10, wherein each of the at least one connection pin is formed in advance and is formed of a material having a melting point higher than about 280° C.

20. The electronic component package according to claim 10, further comprising:
a second electronic component package coupled to the second surface of each of the at least one connection pin.

21. The electronic component package according to claim 20, further comprising a second plating layer or a second solder layer provided between the second surface and the second component package.

22. The electronic component package according to claim 20,
further comprising a second electronic component mounted on the second electronic component package,
wherein the second electronic component is an active element, and the first electronic component is an active or passive element embedded in the first electronic component package.

23. A method for manufacturing the electronic component package according to claim 10, comprising:
providing the first electronic component package; and
fixing the first surface to the first connecting pad,
wherein the first surface has an area larger than that of the second surface.

24. The method according to claim 23, wherein the fixing of the first surface to the first connecting pad is performed by supplying hot wind having a temperature of about 280° C. or less after the first surface contacts a first solder paste in a state in which the first solder paste is applied onto the first connecting pad.

25. The method according to claim 23, further comprising:
coupling a second electronic component package to the connection pin, the second electronic component package including a second electronic component and at least one second connecting pad provided on one surface thereof,
wherein the coupling of the second electronic component package is performed by supplying hot wind having a temperature of about 280° C. or less after the second connecting pad contacts a second solder paste in a state in which the second solder paste is applied onto the second surface.
